(19) United States
(12) Patent Application Publication
(10) Pub. No.: US 2003/0134493 A1
(43) Pub. Date: Jul. 17, 2003

(54) Method for doping Gallium Nitride (GaN) substrates and the resulting doped gan substrate

(76) Inventors: Hak Dong Cho, Cupertino, CA (US); Sang Kyu Kang, Cupertino, CA (US)

Correspondence Address: WILSON SONSINI GOODRICH & ROSATI, 650 PAGE MILL ROAD, PALO ALTO, CA, 943041050

(21) Appl. No.: 10/052,480

(22) Filed: Jan. 17, 2002

(51) Int. Cl. H01L 33/00; H01L 21/261; H01L 21/265; H01L 21/28; H01L 21/3205

(52) U.S. Cl. 438/512; 438/518; 438/522; 257/102

(57) ABSTRACT

A method for doping Gallium Nitride (GaN) substrates is provided wherein Gallium (Ga) is transmuted to Germanium (Ge) by applying thermal neutron irradiation to a GaN substrate material or wafer. The Ge is introduced as an impurity in GaN and acts as a donor. The concentration of Ge introduced is controlled by the thermal neutron flux. When the thermal neutron irradiation is applied to a GaN wafer the fast neutrons are transmuted together with the former and cause defects such as the collapse of the crystallization. The GaN wafer is thermally treated or processed at a fixed temperature to eliminate such defects.

### BACKGROUND OF THE INVENTION

1. Field of the Invention

This invention relates to the field of materials science and more particularly to the doping of Gallium Nitride (GaN) substrates.

2. Description of the Related Art

There is currently a demand in the computer and telecommunication industries for multicolor light emitting displays and improved data density in communication and recording. As a result of this demand, there is a strong desire for a semiconductor light emitting element capable of emitting light having shorter wavelengths ranging from a blue light wavelength to an ultraviolet wavelength.

The 111-V nitrides, as a consequence of their electronic and optical properties and heterostructure character, are highly advantageous for use in the fabrication of a wide range of microelectronic structures. In addition to their wide band gaps, the III-V nitrides also have direct band gaps and are able to form alloys which permit fabrication of well lattice-matched heterostructures. Consequently, devices made from the III-V nitrides can operate at high temperatures, with high power capabilities, and can efficiently emit light in the blue and ultraviolet regions of the electromagnetic spectrum. Devices fabricated from III-V nitrides have applications in full color displays, super-luminescent light-emitting diodes (LEDs), high density optical storage systems, and excitation sources for spectroscopic analysis applications. Furthermore, high temperature applications are found in automotive and aeronautical electronics.

The nitride semiconductor materials are direct transition semiconductor materials and, compared to the available Gallium Arsenide (GaAs) and Indium Phosphide (InP) semiconductor materials, are known to have high thermal conductivity, high-speed electron mobility, a high degree of strength, and are highly stable materials both thermally and chemically. However, the typical nitride semiconductor materials are different from other compound semiconductor materials and, as such, are not able to be produced in the form of ingot-type or bulk-type Gallium Nitride (GaN).

Because the production of bulk-type GaN wafers or substrates has not been feasible, heteroepitaxial methods have been used to produce typical GaN substrates. However, efforts to grow bulk GaN films using typical heteroepitaxy methods on materials including Silicon Carbide (SiC) and Sapphire (Al₂O₃) wafers have resulted in growth layers having large discrepancies in their physical constants.

One problem with the heteroepitaxy substrate materials is found in their high defect density, a defect density on the order of 10⁹-10¹⁰ defects per square centimeter (cm⁻²). The high defect density results from a large mismatch factor resulting from a difference in lattice constants. This defect density in conjunction with the different thermal expansion coefficients associated with the base substrate material and the growth layer leads to cracks in the growth layer or substrate material. In order to reduce or eliminate these problems when using heteroepitaxy substrate materials like SiC or Al₂O₃, it is necessary to develop a homoepitaxy single crystal substrate.

Research in the growth of single crystal GaN substrates to solve the problems inherent in heteroepitaxy methods has continued for many years with virtually no significant gains. The lack of a solution is due to the technical difficulties caused by the relatively large binding energy of GaN, approximately 8.9 electron Volts/atom, and the high partial pressure of nitrogen in homoepitaxial nitride substrates.

The production of nitride semiconductor substrates is complicated by the fact that the GaN dopant partially occupies the Gallium site or the Nitride site. This results in mutual chemical reactions occurring among defects in the material and other impurities. Therefore, obtaining good quality doping in the production of nitride semiconductor substrates is not as easy as in single atom silicon semiconductor materials because it requires precise control of uniform doping and carrier concentrations as well as accurate control of impurities. Consequently, there is a need for a method that overcomes these complications and provides for the production of good quality doped GaN substrates.

### SUMMARY OF THE INVENTION

A method for doping Gallium Nitride (GaN) substrates is provided wherein Gallium (Ga) is transmuted to Germanium (Ge) by applying thermal neutron irradiation to a GaN substrate material or wafer. The Ge is introduced as an impurity in GaN and acts as a donor. The concentration of Ge introduced is controlled by the thermal neutron flux. When the thermal neutron irradiation is applied to a GaN wafer the fast neutrons are transmuted together with the former and cause defects such as the collapse of the crystallization. The GaN wafer is thermally treated or processed at a fixed temperature to eliminate such defects.

The descriptions provided herein are exemplary and explanatory and are provided as examples of the claimed invention.

### BRIEF DESCRIPTION OF THE FIGURES

The accompanying figures illustrate embodiments of the claimed invention. In the figures:

FIG. 1 is a flow chart of a method that provides doped single crystal Gallium Nitride (GaN) substrates and GaN substrate thin films by subjecting GaN substrates to Neutron Transmutation Doping (NTD).

FIG. 2 shows thermal neutron irradiation conditions of an embodiment.

FIG. 3 shows a photoluminescence (PL) spectrum measured at 10K for GaN samples of an embodiment resulting from application of three thermal neutron flux values and thermal annealing.

FIG. 4 shows the PL spectrum measured at 10K for the GaN samples of an embodiment after thermal annealing for 30 minutes at approximately 950° C.

FIG. 5 shows the PL spectrum measured at 10K for the GaN samples of an embodiment after thermal annealing for 30 minutes at approximately 1000° C.

FIG. 6 shows results of the Hall effects measured at room temperature for the GaN samples of an embodiment after treatment with transfer fluxes of approximately 4.146×10¹⁷ neutrons cm⁻², 5.29×10¹⁸ neutrons cm⁻², and 1.09×10¹⁹ neutrons cm⁻², respectively, and thermal annealing for approximately 30 minutes in a nitrogen environment at approximately 1000° C. and 1100° C.

FIG. 7 shows SIMS results measured at room temperature for the GaN samples of an embodiment after treatment with transfer fluxes of approximately 4.146×10¹⁷ neutrons cm⁻² and 30 minutes of thermal annealing at approximately 1100° C.

FIG. 8 shows SIMS results measured at room temperature for the GaN samples of an embodiment after treatment with a transfer flux of approximately 5.29×10¹⁸ neutrons cm⁻² and 30 minutes of thermal annealing at approximately 1000° C.

FIG. 9 shows SIMS results measured at room temperature for the GaN samples of an embodiment after treatment with a transfer flux of approximately 1.09×10¹⁹ neutrons cm⁻² and approximately 30 minutes of thermal annealing at approximately 1000° C.

### DETAILED DESCRIPTION

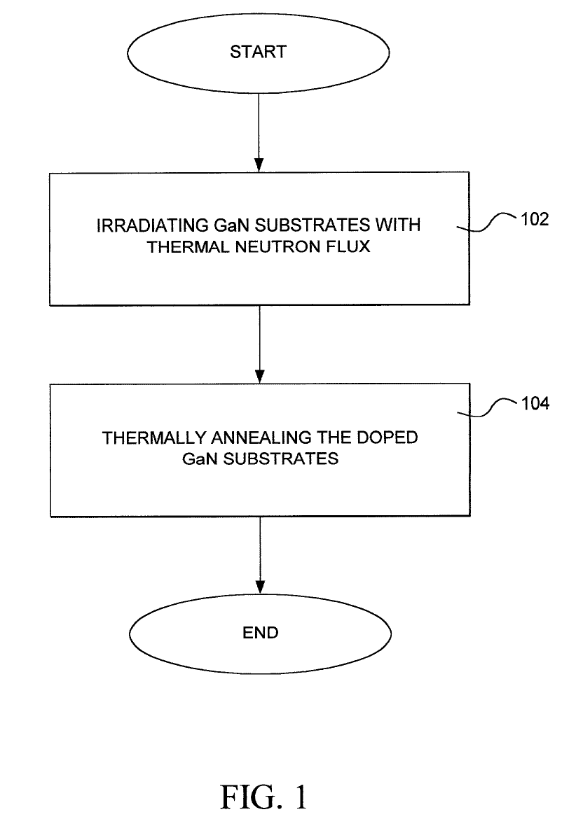

FIG. 1 is a flow chart of a method that overcomes the technical barriers encountered in the doping of Gallium Nitride (GaN) substrates and provides doped single crystal GaN substrates and GaN substrate thin films by subjecting GaN substrates to Neutron Transmutation Doping (NTD), a thermal neutron transmutation method. The method of an embodiment includes doping the GaN material by transmuting Gallium (Ga) into Germanium (Ge) using thermal neutron irradiation fluence 102, or thermal neutron flux, applied to the GaN material. The concentration of the doped Ge is controlled by the flux of the thermal neutrons to which the substrate is subjected. The method further includes thermal annealing 104 of the GaN substrate material doped with Ge at a fixed temperature substantially in the range of 700 to 1200 degrees Celsius. A fixed temperature approximately equal to 1000 degrees Celsius is optimal in an embodiment, but the embodiment is not so limited.

The NTD process takes place when undoped silicon substrates are irradiated in a thermal neutron flux. The purpose of semiconductor doping is to create free electrons. Most compound semiconductors contain at least one element that consists of more than one stable isotope, for example Ga. When using NTD to dope semiconductor materials the largest effects due to isotopic composition occur after the capture of a thermal neutron by the nucleus of a specific isotope. Either the new nucleus is stable and the element remains unchanged, or it decays, transmuting into a new element. In an embodiment this NTD is used to introduce Ge donors into high-purity GaN substrates when the Ge donor atoms are created in the beta decay of an unstable Ga isotope formed when a Ga isotope captures a thermal neutron.

The NTD of an embodiment, as applied to GaN substrates has numerous advantages when compared with other doping methods. One advantage is that the neutrons do not possess an electrical charge. This allows for rather extreme uniformity of doping of impurities regardless of material thickness because, as compared with other doping methods the NTD has the advantage that, provided the isotopes of Ga and N are uniformly distributed, the neutrons are uniformly captured, and therefore the transmuted impurities are distributed uniformly in the samples. Another advantage is that the concentration of impurities is precisely controlled by controlling the neutron dosages.

In an embodiment, GaN material is doped by transmuting Ga to Ge by applying thermal neutron irradiation to the GaN substrate. The transmutation of Ga to Ge introduces Ge as an impurity, and the Ge acts as a donor in the GaN substrate. The concentration of the Ge is determined by the thermal neutron flux.

In response to the thermal neutron irradiation of the GaN substrate, fast neutrons are introduced into the GaN substrate. The fast neutrons create a deficiency environment that can adversely affect crystallization. In order to eliminate the deficiency environment, the doped GaN substrates are thermally annealed at a predetermined temperature. The annealing temperature of an embodiment is a fixed temperature of approximately 1000 degrees Celsius, but is not so limited.

In an embodiment, NTD was performed using thermal neutron irradiation of a GaN substrate with flux values of 4.146×10¹⁷ neutrons/cm²-sec, or neutrons cm⁻², 5.29×10¹⁸ neutrons cm⁻², and 1.09×10¹⁹ neutrons cm⁻². Further, the GaN substrate samples were thermally annealed in a nitrogen environment at 900, 950, 1000, and 1100 degrees Celsius. The features of the samples were examined by measuring sample Photoluminescence (PL), the Hall effect, and Secondary Ion Mass Spectroscopy (SIMS).

The transfer of thermal neutrons to compound semiconductor materials like GaAs or GaN crystals results in the creation of a defect level as described herein. The formula for natural isotope abundance rations and the absorption cross-section of GaN is expressed as follows in equation 1:

Ga⁶⁹(30.2%, 1.68 barn)

Ga⁷¹(19.8%, 4.7 barn)

N¹⁴(49.82%, 1.8 barn) Equation 1

The first item within the parenthesis is the natural isotope abundance ratio, and the second item denotes the absorption cross-section.

When thermal neutrons are transferred to GaN, the isotopes above capture the neutrons first and are transmuted into unstable isotopes as indicated in equation 2, which is followed by their collapse as isotopes by the irradiation of gamma rays and beta rays:

Ga⁶⁹(n, γ)Ga⁷⁰---------→Ge⁷⁰+β⁻(21 minutes)

Ga⁷¹(n, γ)Ga⁷²----→Ge⁷²+β⁻(14.1 hours)

N¹⁴(n, p)C¹⁴-------→N¹⁴+β⁻(5,730 years) Equation 2

In these equations, Ga⁶⁹ (n, γ) Ga⁷⁰ and Ga⁷¹ (n, γ) Ga⁷² expressions indicate that Ga⁶⁹ and Ga⁷¹ are transmuted into isotopes of Ga⁷⁰ and Ga⁷² due to irradiation with gamma rays, which is the result of the transfer of neutrons. The N¹⁴ (n, p) C¹⁴ denotes the transmutation of N¹⁴ to C¹⁴ by the transfer of neutrons, which leads to the discharge of protons.

The Ga⁷⁰, Ga⁷² and C¹⁴ each radiate beta rays and are transmuted into Ge⁷⁰, Ge⁷² and N¹⁴, respectively. The beta is an electron of nuclear origin, and it shares the total energy of the reaction with an electronic antineutrino. These two particles are leptons and in nuclear reactions the sum of the leptons is conserved. The concentrations of Ge⁷⁰, Ge⁷² and N¹⁴ are proportional to the concentrations of Ga⁷⁰, Ga⁷² and C¹⁴, respectively, the integrated thermal neutron flux, and the thermal neutron capture cross section. The time given in parentheses in these expressions is the half-life during which the β⁻ collapse of GaN occurs. Both the Ga⁷¹ and Ga⁷² formed from the nuclear reactions are introduced as impurities in the GaN substrate and act as donors.

The doping concentration of impurities at the time of transmission of neutrons to a compound semiconductor, N_{ntd}, is expressed in equation 3 as:

N_{ntd}=φt ΣnᵢσCⁱ Equation 3

In equation 3, φ is the flux of thermal neutrons, t is the time of transfer, Σ is the ith isotope, σCⁱ is absorption cross section of the ith isotope.

From the relationship between equation 2 and equation 3 it has been calculated that ΣnᵢσCⁱ is approximately 0.16 atom/cm²/neutron/cm² for GaN. Therefore, the doping concentration of impurities can be determined from the flux of thermal neutrons (φ) and time of transfer (t) as follows in equation 4:

N_{ntd}=0.16φt(cm⁻³) Equation 4

Transmuted atoms, however, are not typically located in the original crystal lattice surface following nuclear reactions. As a result of collisions with the crystal lattice caused by the irradiation of gamma rays and beta rays in the process of beta collapse resulting from the absorption of thermal neutrons, the transmuted atoms move to the surface of the crystal or empty Ga and N sites. This results in the formation of defect levels in the GaN substrate. Furthermore, the fast neutrons are not captured in the GaN and form defect levels in the GaN owing to collisions with the crystal lattice. As a result, defect levels including N_{Ga}, Ga_{N}, V_{Ga}, V_{N}, Gaᵢ, and Nₜ are produced in GaN by both thermal neutrons and fast neutrons. Here, N_{Ga} indicates that N is present in the site of Ga, while Ga_{N} indicates that Ga is present in the site of N. In addition, V_{N} and Gaᵢ indicate that each site of N is vacant and Ga occupies intermediate sites.

The defect levels in GaN formed in this manner are reduced in an embodiment using thermal annealing. In particular, a Ge atom that is transmuted and doped in GaN at the critical temperature of at least 1000 degrees Celsius forms a donor level, contributing to the activation of the carrier.

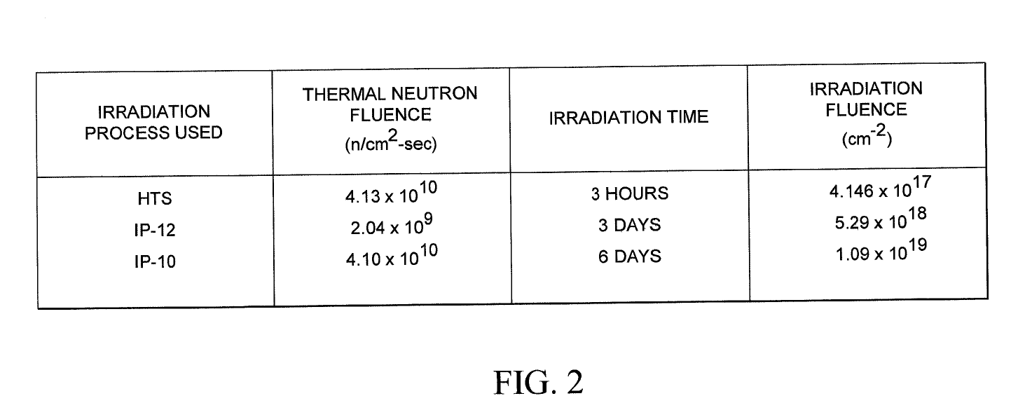

An experimental example with results of the NTD applied to GaN substrates is now provided. The Hanaro nuclear reactor located in the Korea Atomic Energy Research Institute was used for the irradiation of the thermal neutrons of a GaN sample, a representative semiconductor among nitride semiconductors. The generating power of the nuclear reactor used in the experiment was 20 megawatts (MW). The irradiation processes of thermal neutrons included the hydraulic transfer system (HTS) and isotope production (IP). FIG. 2 shows thermal neutron irradiation conditions of an embodiment.

At the time of irradiation, samples were irradiated in a temperature range of 125 to 210 degrees Celsius (° C.) after being wrapped with aluminum foil under different conditions and double-sealed together with Fe and Ni wire (these two are samples used to measure thermal neutrons and fast neutrons) in the container for the irradiation.

The samples were thermally annealed in a nitrogen environment at the temperatures of approximately 900, 950, 1000, and 1100° C. Photoluminescence (PL) was measured at a temperature of approximately 10 Kelvin (K) to confirm the crystallization recovery properties and the optical properties of these samples. In addition, the Hall effect was measured at room temperature in order to examine the doping properties of the Ge atoms transmuted and doped from Ga atoms. In addition, the properties of the samples transmuted and doped by neutrons were examined for 30 minutes at approximately 900° C. in a nitrogen environment by measuring SIMS based on the use of the cesium (Cs) ion for a fixed quantity analysis of the Ge atom.

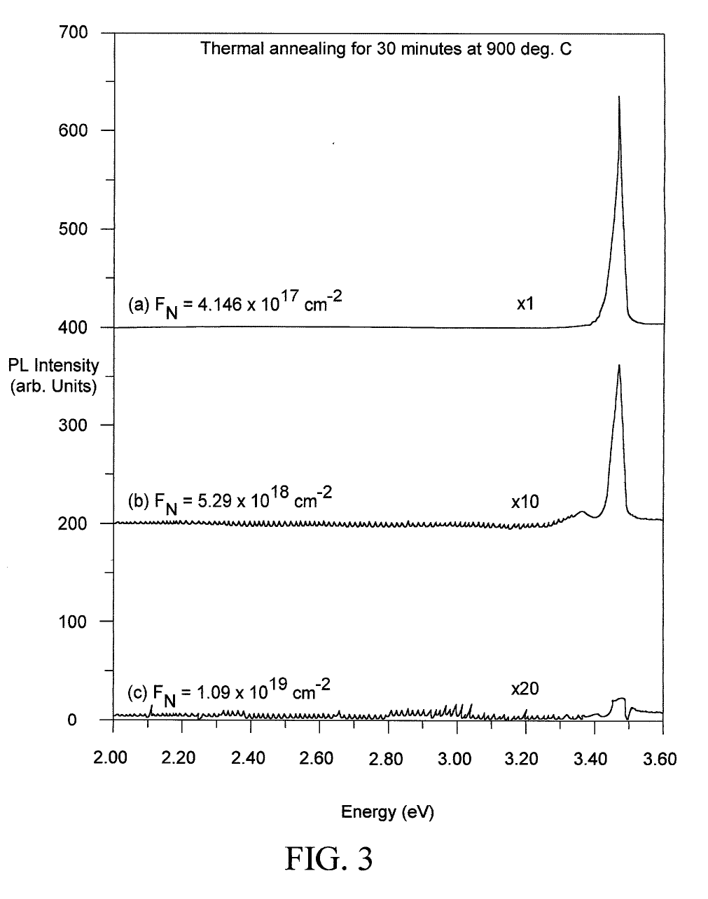

FIG. 3 shows a photoluminescence (PL) spectrum measured at 10K for GaN samples of an embodiment resulting from application of three thermal neutron flux values and thermal annealing. Spectrum (a) is a spectrum of a GaN sample resulting from treatment with a transfer flux of approximately 4.146×10¹⁷ neutrons cm⁻². Spectrum (b) is a spectrum of a GaN sample resulting from treatment with a transfer flux of approximately 5.29×10¹⁸ neutrons cm². Spectrum (c) is a spectrum of a GaN sample resulting from treatment with a transfer flux of approximately 1.09×10¹⁹ neutrons cm⁻².

With reference to FIG. 3, the intensity of the peak associated with the band gap of GaN differs depending upon the size of the flux of thermal neutrons transferred. This is due not only to the thermal neutrons associated with doping at the time of transfer of neutrons to the semiconductor, but also due to the fact that the fast neutrons that cause crystal defects are transferred to the sample, which in turn causes an increase of fast neutrons with the increase of the flux of thermal neutrons transferred, and this is followed by an increase of crystal defects of each sample.

Thus, it can be seen that the extent of re-crystallization is different despite the same thermal annealing conditions.

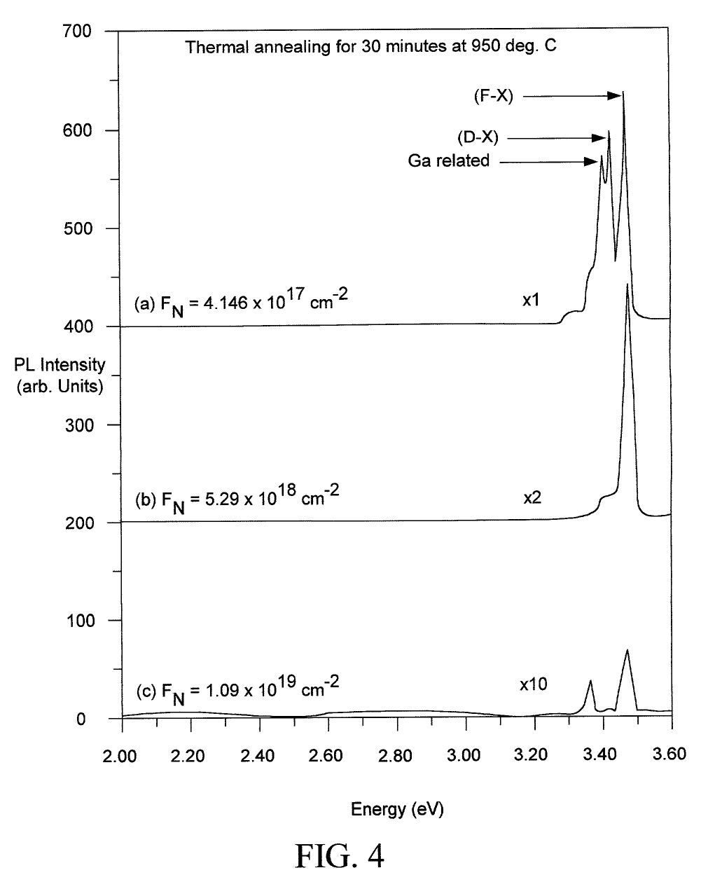

FIG. 4 shows the PL spectrum measured at 10K for the GaN samples of an embodiment after thermal annealing for 30 minutes at approximately 950° C. Spectrum (a) is a spectrum of a GaN sample resulting from treatment with a transfer flux substantially in the range of 4.146×10¹⁷ neutrons cm⁻². Spectrum (b) is a spectrum of a GaN sample resulting from treatment with a transfer flux of approximately 5.29×10¹⁸ neutrons cm⁻². Spectrum (c) is a spectrum of a GaN sample resulting from treatment with a transfer flux of approximately 1.09×10¹⁹ neutrons cm⁻².

Spectrum (a) shows that a peak in (F-X) associated with a band gap around 3.485 electron Volts (eV), a (D₀-X) peak at 3.44 eV, and a peak associated with Ge which is transmuted and doped from Ga around 3.407 eV are observed when the flux of thermal neutrons is approximately 4.146×10¹⁷ neutrons cm⁻². With the increase of the transferred flux amount, the relative intensity of the peak and the peak associated with Ge are observed to decrease due an increase in the flux amount of the transferred fast neutrons that were transferred together with the thermal neutrons. This leads to an increase in crystal defects. Therefore, it seems that crystallization has not yet fully recovered following thermal annealing at approximately 950° C.

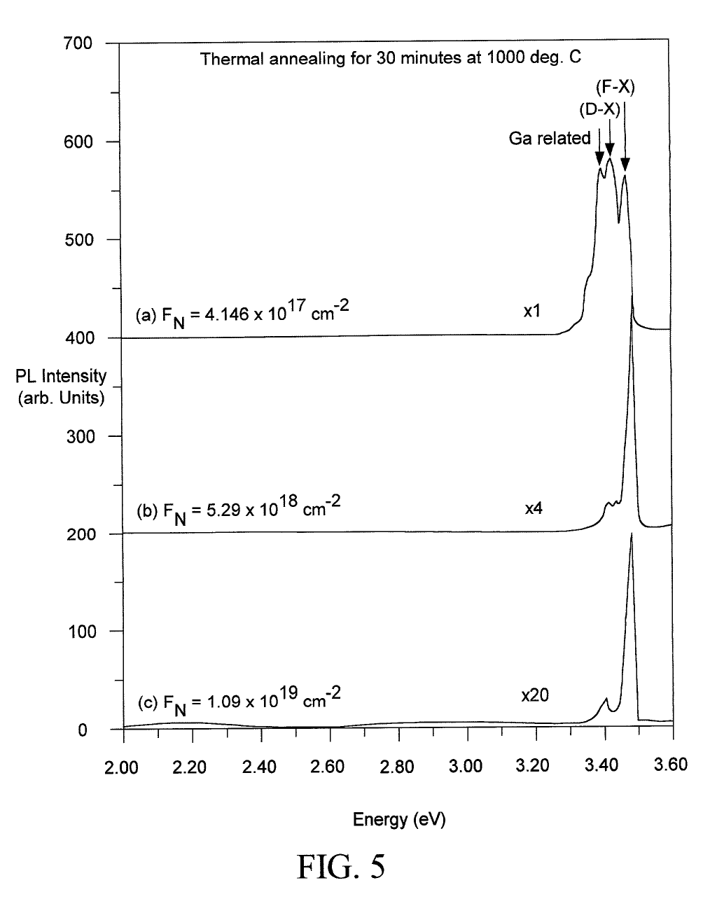

FIG. 5 shows the PL spectrum measured at 10K for the GaN samples of an embodiment after thermal annealing for 30 minutes at approximately 1000° C. Spectrum (a) is a spectrum of a GaN sample resulting from treatment with a transfer flux of approximately 4.146×10¹⁷ neutrons cm⁻². Spectrum (b) is a spectrum of a GaN sample resulting from treatment with a transfer flux of approximately 5.29×10¹⁸ neutrons cm⁻¹. Spectrum (c) is a spectrum of a GaN sample resulting from treatment with a transfer flux of approximately 1.09×10¹⁹ neutrons cm⁻¹.

It is noted that samples transferred at approximately 1.09×10¹⁹ neutrons cm^{31 2} have recovered to a considerable degree the peak associated with the band gap. This indicates that most of the crystal defects in the semiconductor materials resulting from the fast neutrons have recovered with the increase in thermal annealing temperature.

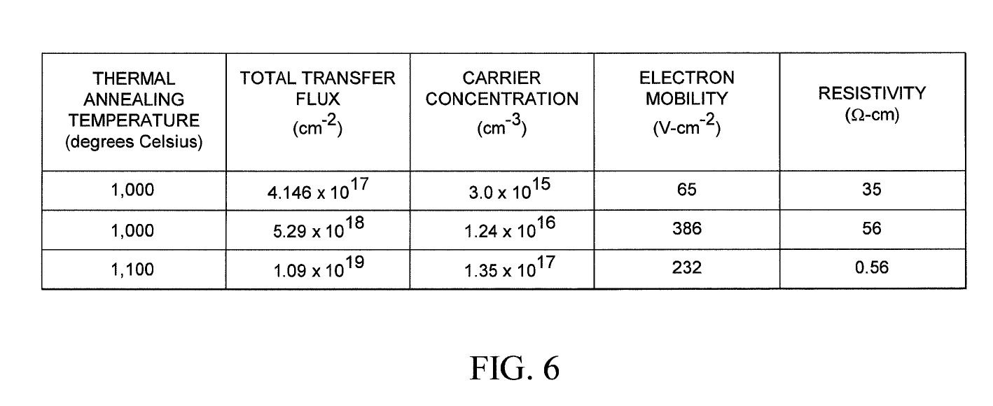

FIG. 6 shows results of the Hall effects measured at room temperature for the GaN samples of an embodiment after treatment with transfer fluxes of approximately 4.146×10¹⁷ neutrons cm⁻², 5.29×10¹⁸ neutrons cm⁻², and 1.09×10¹⁹ neutrons cm⁻², respectively, and thermal annealing for approximately 30 minutes in a nitrogen environment at approximately 1000° C. The total flux of transferred thermal neutrons is about 100 times higher than the concentration of the carrier. This indicates that the Ga atoms in the GaN crystal are about 50% of the atom rate. Although there is little difference in the results for the electron mobility and resistance value, crystallization has almost fully recovered. For the samples exposed to a transfer flux of approximately 5.29×10¹⁸ neutrons cm⁻², the electron mobility is the highest at 386V·cm⁻³.

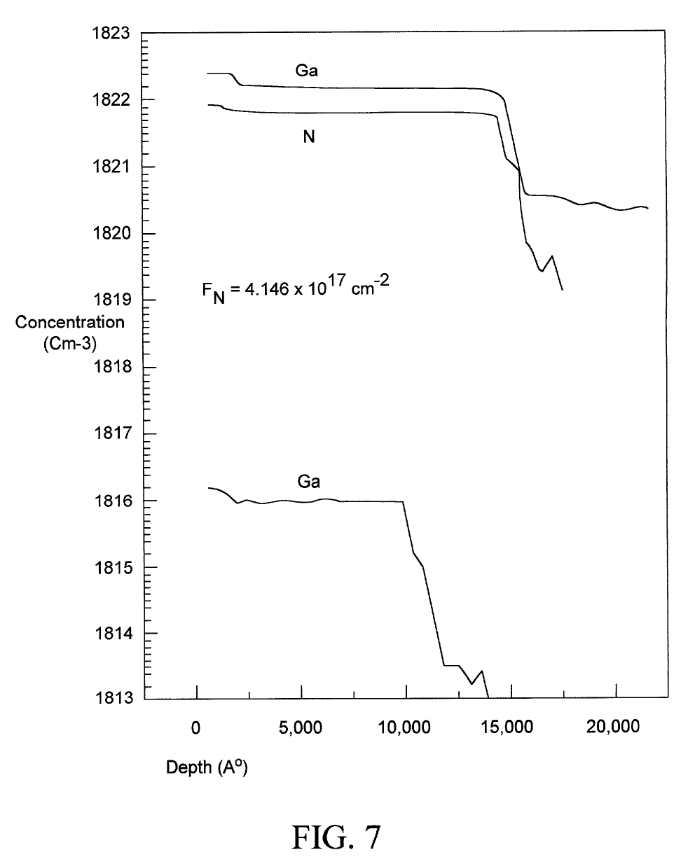

FIG. 7 shows SIMS results measured at room temperature for the GaN samples of an embodiment after treatment with transfer fluxes of approximately 4.146×10¹⁷ neutrons cm⁻² and 30 minutes of thermal annealing at approximately 1000° C. The concentration of Ge transmuted from Ga in GaN crystals is approximately 1.1×10¹⁶ cm⁻³. This value is about 10 percent of the total flux of transferred neutrons and about 10 times larger than the measurements for the Hall effect. As discussed herein, this result is associated with the fact that Ga atoms have about 50% of the atom rate in GaN crystals, and the result shows that crystal defects have not been fully solved and crystallization has not yet fully recovered by thermal annealing.

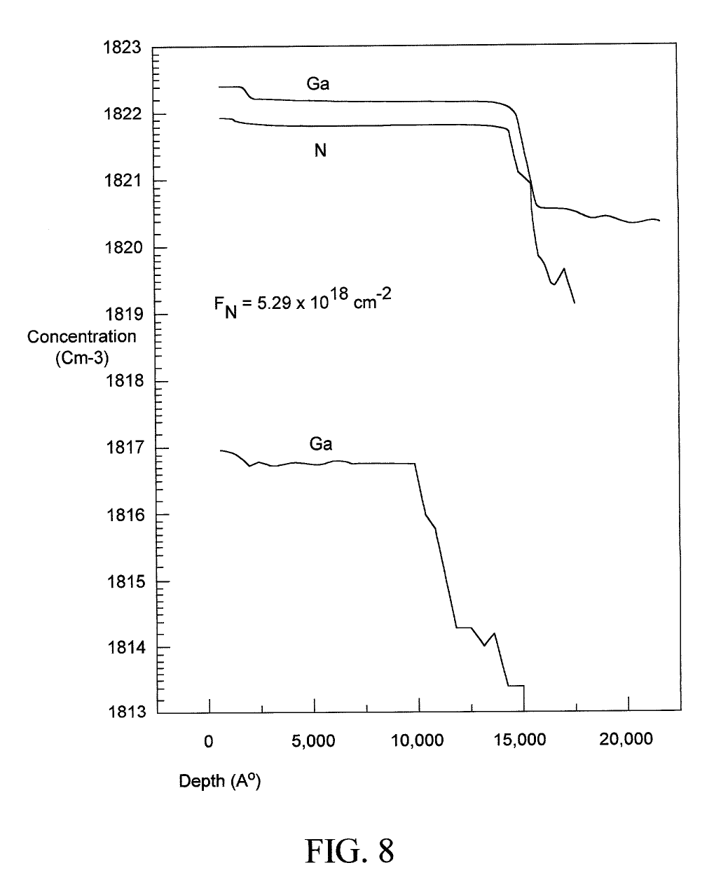

FIG. 8 shows SIMS results measured at room temperature for the GaN samples of an embodiment after treatment with a transfer flux of approximately 5.29×10¹⁸ neutrons cm⁻² and 30 minutes of thermal annealing at approximately 1000° C. The concentration of Ge transmuted from Ga in the GaN crystal is approximately 7×10¹⁶ cm⁻³. As discussed herein, this value is smaller than the total flux of neutrons transferred to the sample and larger than the measurements obtained from the Hall effect measurements. This result is associated with the fact that the Ga atoms have about 50% of the atom rate in GaN crystals.

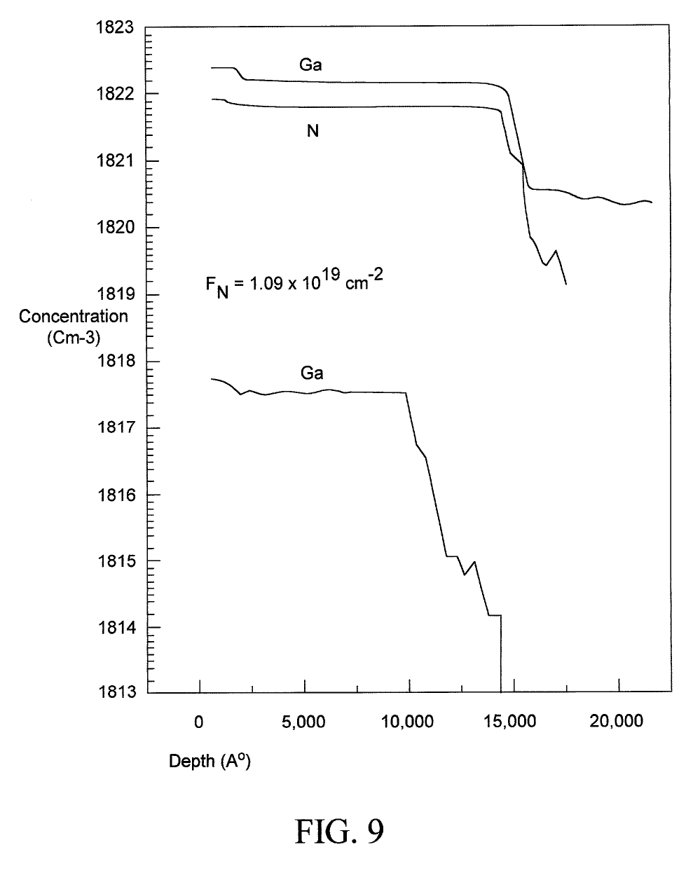

FIG. 9 shows SIMS results measured at room temperature for the GaN samples of an embodiment after treatment with a transfer flux of approximately 1.09×10¹⁹ neutrons cm⁻² and approximately 30 minutes of thermal annealing at approximately 1000° C. The concentration of Ge transmuted and doped in the GaN crystals is approximately 4×10¹⁷ cm⁻³. The result is that only Ga is transmuted and doped as a donor in GaN, while both Ga and As both are involved in doping as donors in GaAs, which is also a compound semiconductor.

Although the claimed invention is described in terms of specific embodiments, it will be understood that numerous variations and modifications may be made without departing from the spirit and scope of the claimed invention as described herein and as set forth in the accompanying claims.

What is claimed is:

1. A method for producing doped Gallium Nitride (GaN) substrates, comprising:
irradiating undoped GaN substrates with a thermal neutron flux that produces isotopes of Gallium (Ga), wherein the doped GaN substrates are produced when the isotopes of Ga transmute into Germanium (Ge); and
thermally annealing the doped GaN substrates.

2. The method of claim 1, wherein the isotopes of Ga include at least one isotope selected from a group consisting of Ga⁷⁰ and Ga⁷².

3. The method of claim 2, wherein the Ga⁷⁰ isotope transmutes into Ge⁷⁰.

4. The method of claim 2, wherein the Ga⁷² isotope transmutes into Ge⁷².

5. The method of claim 1, wherein the thermal neutron flux is selected from a group consisting of 4.146×10¹⁷ neutrons/cm²-second, 5.29×10¹⁸ neutrons/cm²-second, and 1.09×10¹⁹ neutrons/cm⁻²-second.

6. The method of claim 1, wherein thermally annealing comprises thermally annealing the doped GaN substrates in a nitrogen environment at a fixed temperature substantially in the range 700 to 1200 degrees Celsius.

7. The method of claim 1, wherein a doping concentration of Ge is determined from a flux of thermal neutrons (¢) and time of transfer (t) as N_{ntd}, wherein N_{ntd}=0.16φt(cm⁻³).

8. A doped GaN substrate material prepared by irradiating undoped GaN substrates with a thermal neutron flux that produces isotopes of Ga, wherein the doped GaN substrates are produced when the isotopes of Ga transmute into Ge, and thermally annealing the doped GaN substrates.

9. The doped GaN substrate material of claim 8, wherein the isotopes of Ga include at least one isotope selected from a group consisting of Ga⁷⁰ and Ga⁷².

10. The doped GaN substrate material of claim 9, wherein the Ga⁷⁰ isotope transmutes into Ge⁷⁰.

11. The doped GaN substrate material of claim 9, wherein the Ga⁷² isotope transmutes into Ge⁷².

12. The doped GaN substrate material of claim 8, wherein the thermal neutron flux is selected from a group consisting of 4.146×10¹⁷ neutrons/cm²-second, 5.29×10¹⁸ neutrons/cm²-second, and 1.09×10¹⁹ neutrons/cm⁻²-second.

13. The doped GaN substrate material of claim 8, wherein thermally annealing comprises thermally annealing the doped GaN substrates in a nitrogen environment at a fixed temperature substantially in the range 700 to 1200 degrees Celsius.

14. The doped GaN substrate material of claim 8, wherein a doping concentration of Ge is determined from a flux of thermal neutrons (φ) and time of transfer (t) as N_{ntd}, wherein N_{ntd}=0.16φt(cm⁻³).

15. A nitride semiconductor device comprising a doped GaN substrate material prepared by irradiating undoped GaN substrates with a thermal neutron flux that produces isotopes of Ga, wherein the doped GaN substrates are produced when the isotopes of Ga transmute into Ge, and thermally annealing the doped GaN substrates.

16. The nitride semiconductor device of claim 15, wherein the isotopes of Ga include at least one isotope selected from a group consisting of Ga⁷⁰ and Ga⁷².

17. The nitride semiconductor device of claim 16, wherein the Ga⁷⁰ isotope transmutes into Ge⁷⁰.

18. The nitride semiconductor device of claim 16, wherein the Ga⁷² isotope transmutes into Ge⁷².

19. The nitride semiconductor device of claim 15, wherein the thermal neutron flux is selected from a group consisting of 4.146×10¹⁷ neutrons/cm²-second, 5.29×10¹⁸ neutrons/cm²-second, and 1.09×10¹⁹ neutrons/cm⁻²-second.

20. The nitride semiconductor device of claim 15, wherein thermally annealing comprises thermally annealing the doped GaN substrates in a nitrogen environment at a fixed temperature substantially in the range 700 to 1200 degrees Celsius.

21. The nitride semiconductor device of claim 15, wherein a doping concentration of Ge is determined from a flux of thermal neutrons (φ) and time of transfer (t) as Nntd, wherein N_{ntd}=0.16φt(cm⁻³).

22. A light emitting device comprising a nitride semiconductor device, the nitride semiconductor device comprising a doped GaN substrate material prepared by irradiating undoped GaN substrates with a thermal neutron flux that produces isotopes of Ga, wherein the doped GaN substrates are produced when the isotopes of Ga transmute into Ge, and thermally annealing the doped GaN substrates.

23. The light emitting device of claim 22, wherein the isotopes of Ga include at least one isotope selected from a group consisting of Ga⁷⁰ and Ga⁷².

24. The light emitting device of claim 23, wherein the Ga⁷⁰ isotope transmutes into Ge⁷⁰.

25. The light emitting device of claim 23, wherein the Ga⁷² isotope transmutes into Ge⁷².

26. The light emitting device of claim 22, wherein the thermal neutron flux is selected from a group consisting of 4.146×10¹⁷ neutrons/cm²-second, 5.29×10¹⁸ neutrons cm²-second, and 1.09×10¹⁹ neutrons/cm⁻²-second.

27. The light emitting device of claim 22, wherein thermally annealing comprises thermally annealing the doped GaN substrates in a nitrogen environment at a fixed temperature substantially in the range 700 to 1200 degrees Celsius.

28. The light emitting device of claim 22, wherein a doping concentration of Ge is determined from a flux of thermal neutrons (φ) and time of transfer (t) as N_{ntd}, wherein N_{ntd}=0.16φt(cm⁻³).

29. A composition of matter for a nitride semiconductor device comprising a doped GaN substrate material prepared by irradiating undoped GaN substrates with a thermal neutron flux that produces isotopes of Ga, wherein the doped GaN substrates are produced when the isotopes of Ga transmute into Ge, and thermally annealing the doped GaN substrates.

30. The composition of matter of claim 29, wherein the isotopes of Ga include at least one isotope selected from a group consisting of Ga⁷⁰ and Ga⁷².

31. The composition of matter of claim 30, wherein the Ga⁷⁰ isotope transmutes into Ge⁷⁰.

32. The composition of matter of claim 30, wherein the Ga⁷² isotope transmutes into Ge⁷².

33. The composition of matter of claim 29, wherein the thermal neutron flux is selected from a group consisting of 4.146×10¹⁷ neutrons/cm²-second, 5.29×10¹⁸ neutrons/cm²-second, and 1.09×10¹⁹ neutrons/cm⁻²-second.

34. The composition of matter of claim 29, wherein thermally annealing comprises thermally annealing the doped GaN substrates in a nitrogen environment at a fixed temperature substantially in the range 700 to 1200 degrees Celsius.

35. The composition of matter of claim 29, wherein a doping concentration of Ge is determined from a flux of thermal neutrons (φ) and time of transfer (t) as N_{ntd}, wherein N_{ntd}=0.16φt(cm⁻¹).
